(19) United States
(12) Patent Application Publication
(10) Pub. No.: US 2025/0351292 A1
(43) Pub. Date: Nov. 13, 2025

(54) HEAT DISSIPATION DEVICE

(71) Applicant: PURPLE CLOUD DEVELOPMENT PTE. LTD., Singapore (SG)

(72) Inventors: DACHANG YIN, Hui Zhou City (CN); SHI MAN XU, Hui Zhou City (CN)

(73) Assignee: PURPLE CLOUD DEVELOPMENT PTE. LTD., Singapore (SG)

(21) Appl. No.: 19/098,622

(22) Filed: Apr. 2, 2025

(30) Foreign Application Priority Data
May 7, 2024 (CN) 202420973413.7

(51) Int. Cl. H05K 7/20

(52) U.S. Cl. CPC H05K 7/20172

(57) ABSTRACT

A heat dissipation device includes a plurality of cooling fans and at least one fastening device that includes a main body, a fastening kit having two arms each includes two first connecting parts, a second connecting part, and a pressing structure, a first end of the two first connecting parts connect to opposite ends of the second connecting part and a second end of the two first connecting parts connect to an outer surface of the main body, the pressing structure disposes on the second connecting part and protrudes out of the outer surface of the main body, and each arm includes two snap-fit joints, and a contact plate disposed on an inner surface of the main body, the contact plate includes plurality of contact pins that are disposed on opposite ends of the contact plate, wherein, the snap-fit joints are configured to snap fit to the cooling fans so that the contact pins are electrically connected to the cooling fans.

### RELATED APPLICATIONS

The present application claims priority to Chinese application No. 202420973413.7, filed on May 7, 2024, which is incorporated herein by reference in its entirety.

### TECHNICAL FIELD

The present disclosure is related to the field of heat dissipation devices, in particular a heat dissipation device that unitizes snap-fit joints.

### BACKGROUND

As technology advances and consumer demands change, every cooling fan in a cooling device with multiple cooling fans will have its own test wire for testing and subsequent maintenance to verify the fan's operational state. As market demands change, multi-fan combinations are becoming more popular, especially in desktop computers or high-end servers.

When multiple cooling fans are tightly combined in the same cooling device, the built-in independent test wire may cause a series of problems for users. For example, due to the presence of multiple test wires, the users may encounter additional challenges when arranging wires. In addition, the interlacement and entanglement between the test wires can affect the neatness of the device's interior, as well as obstruct air flow, which in turn affects the device's heat dissipation efficiency.

### SUMMARY

Aspects of the disclosure provide a heat dissipation device having a plurality of cooling fans and at least one fastening device. The fastening device includes a main body with a fastening kit having two arms and each of the arm including two first connecting parts, a second connecting part, and a pressing structure, a first end of the two first connecting parts connect to opposite ends of the second connecting part and a second end of the two first connecting parts connect to an outer surface of the main body, the pressing structure disposes on the second connecting part and protrudes out of the outer surface of the main body, and each arm includes two snap-fit joints, and a contact plate disposed on an inner surface of the main body that is opposite to the outer surface, the contact plate includes plurality of contact pins that are disposed on opposite ends of the contact plate, wherein, the snap-fit joints are configured to snap fit to the cooling fans so that the contact pins are electrically connected to the cooling fans.

In an embodiment, the cooling fans each has a plurality of snap-fit grooves that each is configured to receive the snap-fit joint correspondingly. In an embodiment, each snap-fit joint is disposed on each first connecting part correspondingly. In an embodiment, the main body includes two chamfered corners.

In an embodiment, the fastening device includes four notches where the snap-fit joints and a portion of the first connecting parts are disposed within the corresponding notch.

In an embodiment, the fastening device includes a reinforcing structure so that the contact plate is disposed between the main body and the reinforcing structure, the reinforcing structure is fastened to the main body, the main body, the contact plate, and the reinforcing structure are aligned with a centerline, and the reinforcing structure is shorter than the contact plate in length so portions of the contact plate are exposed at the opposite ends.

Aspects of the disclosure provide a fastening device that includes a main body, a fastening kit having two arms each includes two first connecting parts and a second connecting part, a first end of the two first connecting parts connect to opposite ends of the second connecting part and a second end of the two first connecting parts connect to an outer surface of the main body, and each arm includes two snap-fit joints, and a contact plate disposed on an inner surface of the main body that is opposite to the outer surface, the contact plate includes plurality of contact pins that are disposed on opposite ends of the contact plate.

Aspects of the disclosure provide a heat dissipation device having a plurality of cooling fans and at least one fastening device. Each of the cooling fans includes a plurality of snap-fit grooves and a plurality of contact panels, each contact panel includes a plurality of conductive pins. The fastening device includes a main body, a fastening kit having two arms each includes two first connecting parts, a second connecting part, and a pressing structure, a first end of the two first connecting parts connect to opposite ends of the second connecting part and a second end of the two first connecting parts connect to an outer surface of the main body, the pressing structure disposes on the second connecting part and protrudes out of the outer surface of the main body, and each includes two snap-fit joints, and a first contact plate disposed on an inner surface of the main body that is opposite to the outer surface, the first contact plate includes plurality of contact pins that are disposed on opposite ends of the first contact plate, wherein, the snap-fit joints are configured to snap fit to the corresponding snap-fit grooves of the cooling fans so that the contact pins are electrically connected to corresponding contact panels of the cooling fans so that the cooling fans are connected to each other in series.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a perspective view of a heat dissipation device 20 according to aspects of the present disclosure.

FIG. 2 illustrates a exploded view of a fastening device 10 according to aspects of the present disclosure.

FIG. 3 illustrates a partially enlarged view of the heat dissipation device 20 as shown in FIG. 1.

FIG. 4 illustrates a partially exploded view of the heat dissipation device 20 as shown in FIG. 1.

FIG. 5 illustrates a top view of the heat dissipation device 20 as shown in FIG. 1.

FIG. 6 illustrates a bottom view of the heat dissipation device 20 as shown in FIG. 1.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

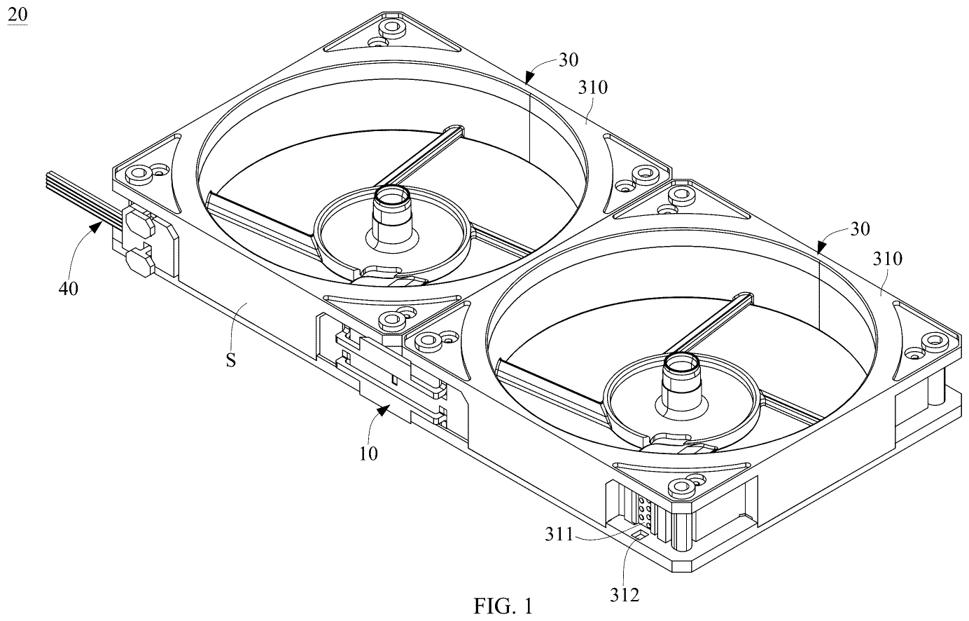

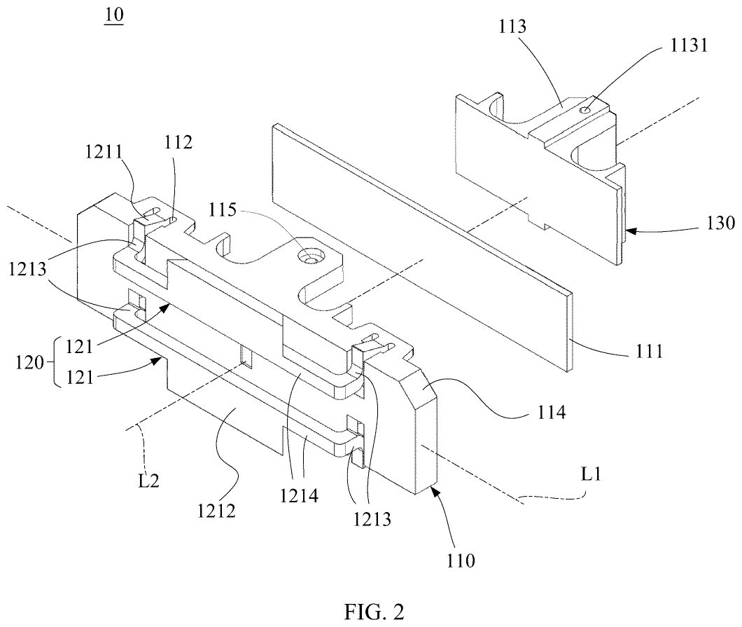

Referring to FIGS. 1-2. FIG. 1 illustrates a perspective view of a heat dissipation device 20 according to aspects of the present disclosure. FIG. 2 illustrates an exploded view of a fastening device 10 according to aspects of the present disclosure. The heat dissipation device 20 can include multiple cooling fans 30, a wire connector 40, and a fastening device 10. Each cooling fans 30 can include a housing 310, multiple blades (not shown), and a motor (not shown). The fastening device 10 is used to connect two cooling fans 30 together. For example, as shown in FIG. 1, one fastening device 10 is used to connect two cooling fans 30. For another example, two fastening devices 10 is needed to connect three cooling fans 30.

The fastening device 10 includes a main body 110, a contact plate 111, and a reinforcer 130. The main body 110 includes a fastening kit 120 that are integrated with the main body 110. The fastening kit 120 has two elastic arms 121 that each includes two first connecting parts 1213 and a second connecting part 1214. The first connecting parts 1213 are connected to opposite ends of the second connecting part 1214. The first connecting parts 1213 are integrated with the main body 110. The two elastic arms 121 are disposed axially and symmetrically with a central axis L1 of the main body 110. Each first connecting part 1213 has a snap-fit joint 1211 that is used to snap-fit to the housing 310 of the cooling fan 30. A notch 112 is left adjacent to the location where the first connecting part 1213 is integrated with the main body 110. The notch 112 can provide some adjustment space for the snap-fit joint 1211 after the elastic arm 121 is deformed to be securely fitted to a snap-fit groove 312 on the housing 310 of the cooling fan 30.

Each elastic arm 121 further can include a pressing structure 1212. The pressing structure 1212 can protrude out of the external surface S of the housing 310 as shown in FIG. 1. In this way, the pressing structure 1212 can be easily reached by the user to engage the fastening kit 120, and in turn increase the fastening efficiency. In action, the two elastic arms 121 of the fastening kit 120 can be pressed toward each other to disengage the snap-fit joint 1211 with the snap-fit grooves 312 of the cooling fans 30. The two snap-fit joints 1211 on the same side (i.e., left side) are connected to one cooling fan 30, therefore, one fastening device 10 can connect two cooling fans 30 together.

The main body 110 can further include a through hole 115 and chamfered structures 114. The through hole is located along the center line of the main body 110. The chamfered structures 114 can located at the upper edges of the main body 110 and provide a tighter fit when assembled with the cooling fans. This can reduce the frictional resistance and stress concentration during assembling as well as during operation, improving the quality and efficiency of the heat dissipation device 20.

The contact plate 111 is disposed between the main body 110 and the reinforcer 130. The contact plate 111 can include multiple contact pins (not shown) that are in pairs. Two contact pins in a pair are disposed on opposite ends of the contact plate 111 and are connected electrically. The reinforcer 130 is shorter than the contact plate 111 so that two longitudinal ends of the contact plate 111 are exposed. The main body 110, the contact plate 111, and the reinforcer 130 are disposed center symmetrically along the center line L2. In this way, the two exposed ends of the contact plate 111 are equal in terms of surface area. Further, a center portion 113 of the reinforcer 130 include a threaded through hole 1131 that, when assembled with the main body 110, is aligned with the through hole 115. This can allow a screw or pin (not shown) to secure the contact plate 111 between the main body 110 and the reinforcer 130. The through hole 115 and the threaded through hole 1131 ensure a center alignment in the main body 110, contact plate 111, and the reinforcer 130. Further, the center portion 113 provides reinforcement to the fastening device 10, improving the structural rigidity of the fastening device 10. In some embodiments, the reinforcer 130 can also be integrated with the main body 110. For example, the reinforcer 130 can be made with the main body 110 in a single process and a gap is left between the reinforcer 130 and the main body 110 for the contact plate 111 to be inserted in.

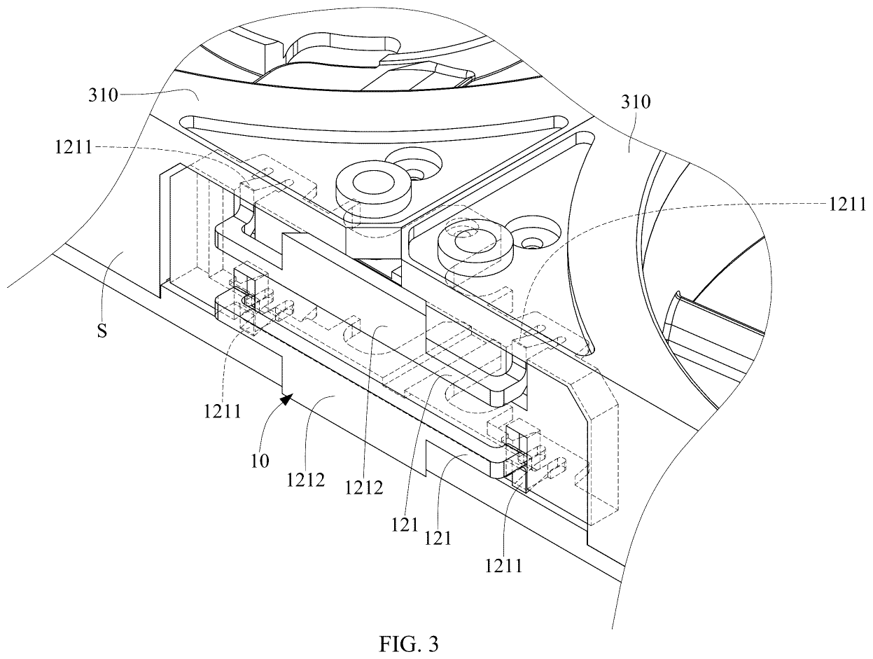

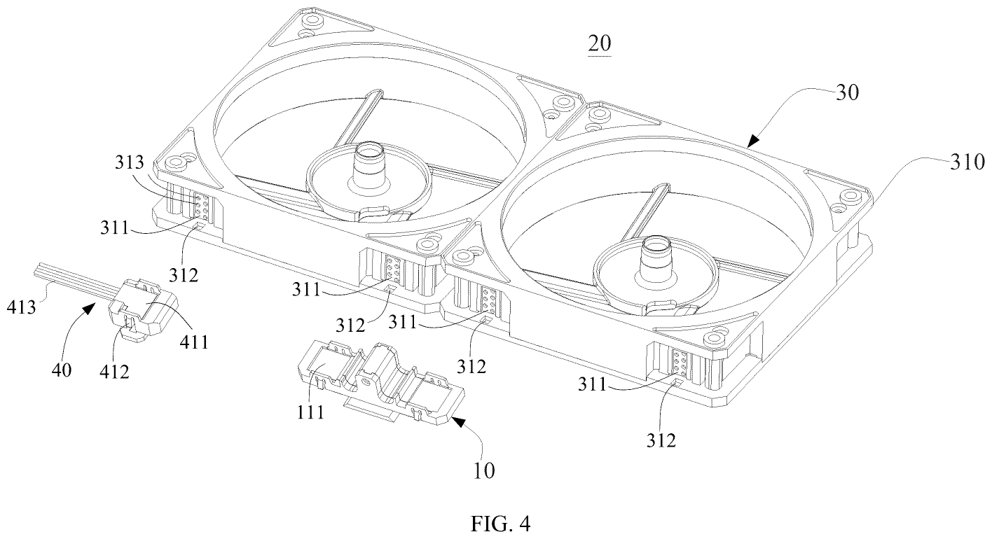

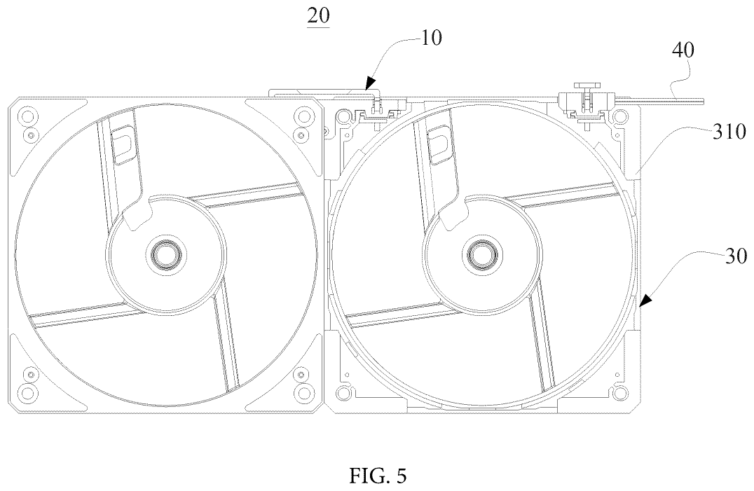

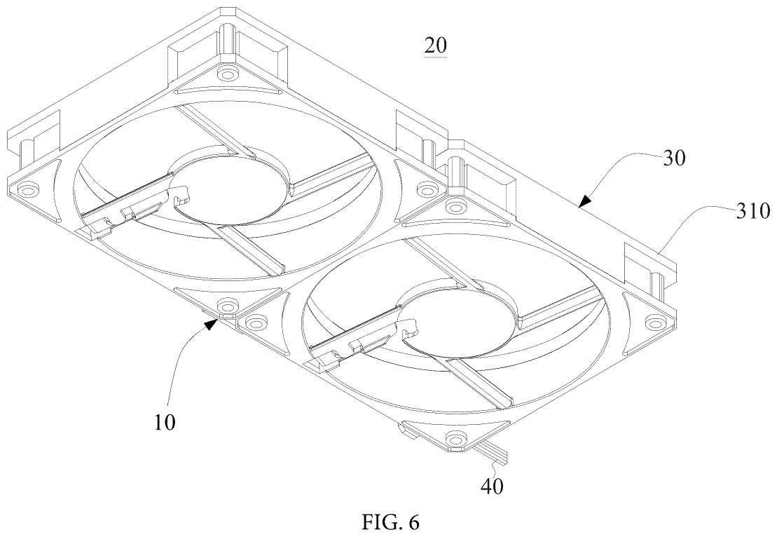

Please also refer to FIGS. 3-6. FIG. 3 illustrates a partially enlarged view of the heat dissipation device 20 as shown in FIG. 1. FIG. 4 illustrates a partially exploded view of the heat dissipation device 20 as shown in FIG. 1. FIG. 5 illustrates a top view of the heat dissipation device 20 as shown in FIG. 1. FIG. 6 illustrates a bottom view of the heat dissipation device 20 as shown in FIG. 1.

Each cooling fan 30 includes at least two contact panels 311 that each can includes multiple conductive pins 313. The conductive pins 313 can be made of any conductive material. For example, the conductive pins 313 can be made of copper, silver, or gold, or any combination thereof. Each contact panel 311 has the same number of conductive pins 313. The number of conductive pins 313 on each contact panel 311 is equal to the number of contact pins on one side of the contact plate 111. The contact panels 311 of a single cooling fan 30 are electrically connected to each other internally of the housing 310. The contact panels 311 are also electrically connected to other components of the cooling fan 30 internally. For example, two corresponding conductive pins on the contact panels 311 can connect to a corresponding component within the cooling fan 30. When the heat dissipation device 20 is fully assembled, the conductive pins of the contact panels 311 are in contact with the contact plate 111 of the fastening device 10. As such, any two cooling fans 30 can be connected in series through the adjacent two contact panels 311 and the fastening device 10.

The wire connector 40 includes a contact plate 411, two snap-fit joints 412 and wires 413. Similar to the contact plate 111, the contact plate 411 can include multiple contact pins (not shown). Each contact pin is corresponding to one wire 413 or a set of wires 413. The snap-fit joints 412 can be inserted into the snap-fit groove 312 and secure the wire connector 40 to the cooling fan 30. The wires 413 can be connected to an external power source (not shown) or other components of a PC or a server. The wires 413 can provide power to the heat dissipation device 20. The wires 413 can also provide data to and from the heat dissipation device 20 during operation and testing. Each of contact pins is electrically connected to a corresponding conductive pin 313 of the cooling fan 30. As such, the heat dissipation device 20 can have two cooling fans 30 connected to each other in series via the fastening device 10, and to external components via the wire connector 40.

By utilizing the fastening device 10 and the wire connector 40, cooling fans 30 can eliminate individual wires that may be exposed, reducing the necessity for complex wire arrangement. A single wire connector and plurality of fastening device can connect multiple cooling fans together, which makes the heat dissipation device infinitely expandable to suit a wide range of application. Furthermore, by lowering the number of exposed wires within, the neatness of interior heat dissipation device 20 can be improved as can the influence of the wires on the airflow, thereby improving the heat dissipation efficiency of the heat dissipation device 20.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. A heat dissipation device, comprising:
a plurality of cooling fans; and
at least one fastening device, comprising:
a main body;
a fastening kit having two arms each includes two first connecting parts, a second connecting part, and a pressing structure, a first end of the two first connecting parts connect to opposite ends of the second connecting part and a second end of the two first connecting parts connect to an outer surface of the main body, the pressing structure disposes on the second connecting part and protrudes out of the outer surface of the main body, and each arm includes two snap-fit joints; and
a contact plate disposed on an inner surface of the main body that is opposite to the outer surface, the contact plate includes plurality of contact pins that are disposed on opposite ends of the contact plate,
wherein the snap-fit joints are configured to snap fit to the cooling fans so that the contact pins are electrically connected to the cooling fans.

2. The heat dissipation device of claim 1, wherein the cooling fans each has a plurality of snap-fit grooves that each is configured to receive the snap-fit joint correspondingly.

3. The heat dissipation device of claim 1, wherein each snap-fit joint is disposed on each first connecting part correspondingly.

4. The heat dissipation device of claim 1, wherein the main body includes two chamfered corners.

5. The heat dissipation device of claim 1, wherein the fastening device includes four notches where the snap-fit joints and a portion of the first connecting parts are disposed within the corresponding notch.

6. The heat dissipation device of claim 1, wherein the fastening device includes a reinforcing structure so that the contact plate is disposed between the main body and the reinforcing structure, the reinforcing structure is fastened to the main body, the main body, the contact plate, and the reinforcing structure are aligned with a centerline, and the reinforcing structure is shorter than the contact plate in length so portions of the contact plate are exposed at the opposite ends.

7. A fastening device, comprising:
a main body;
a fastening kit having two arms each includes two first connecting parts and a second connecting part, a first end of the two first connecting parts connect to opposite ends of the second connecting part and a second end of the two first connecting parts connect to an outer surface of the main body, and each arm includes two snap-fit joints; and
a contact plate disposed on an inner surface of the main body that is opposite to the outer surface, the contact plate includes plurality of contact pins that are disposed on opposite ends of the contact plate.

8. The fastening device of claim 7, wherein each arm includes a pressing structure that is disposed on the second connecting part and protrudes out of the outer surface of the main body.

9. The fastening device of claim 7, further comprises four notches where the snap-fit joints and a portion of the first connecting parts are disposed within the corresponding notch.

10. The fastening device of claim 7, further comprises a reinforcing structure so that the contact plates are disposed between the main body and the reinforcing structure, the reinforcing structure is connected to the main body, the main body, the contact plate, and the reinforcing structure are aligned with a centerline, and the reinforcing structure is shorter than the contact plate in length so portions of the contact plate are exposed at the opposite ends.

11. The fastening device of claim 10, wherein the reinforcing structure is integrated with the main body.

12. The fastening device of claim 10, wherein the reinforcing structure is connected to the main body with a screw that threads through center aligned though holes on the main body and the reinforcing structure.

13. The fastening device of claim 7, wherein the main body includes two chamfered corners.

14. A heat dissipation device, comprising:
a plurality of cooling fans that each includes a plurality of snap-fit grooves and a plurality of contact panels, each contact panel includes a plurality of conductive pins; and
at least one fastening device, comprising:
a main body;
a fastening kit having two arms each includes two first connecting parts, a second connecting part, and a pressing structure, a first end of the two first connecting parts connect to opposite ends of the second connecting part and a second end of the two first connecting parts connect to an outer surface of the main body, the pressing structure disposes on the second connecting part and protrudes out of the outer surface of the main body, and each arm includes two snap-fit joints; and
a first contact plate disposed on an inner surface of the main body that is opposite to the outer surface, the first contact plate includes plurality of contact pins that are disposed on opposite ends of the first contact plate,
wherein the snap-fit joints are configured to snap fit to the corresponding snap-fit grooves of the cooling fans so that the contact pins are electrically connected to corresponding contact panels of the cooling fans so that the cooling fans are connected to each other in series.

15. The heat dissipation device of claim 14, wherein each cooling fan includes a housing, a plurality of fan blades, and a motor, the snap-fit grooves are disposed on the housing, the fan blades are disposed in the housing, the fans blades are configured to rotate relative to the housing, and the motor is electrically connected to the fan blades.

16. The heat dissipation device of claim 14, further comprises a wire connector that includes at least one snap-fit joint, a plurality of wires and a second contact plate, the second contact plate is configured to be electrically connect to one of the contact panels of the cooling fans.

17. The heat dissipation device of claim 14, wherein the fastening device includes four notches where the snap-fit joints and a portion of the first connecting parts are disposed within the corresponding notch.

18. The heat dissipation device of claim 14, wherein the fastening device includes a reinforcing structure so that the contact plate is disposed between the main body and the reinforcing structure, the reinforcing structure is fastened to the main body, the main body, the contact plate, and the reinforcing structure are aligned with a centerline, and the reinforcing structure is shorter than the contact plate in length so portions of the contact plate are exposed at the opposite ends.

19. The heat dissipation device of claim 14, wherein the main body includes two chamfered corners.

20. The heat dissipation device of claim 19, wherein the cooling fans include at least one chamfered corner that is configured to receive one of the chamfered corners of the main body.
